(19) United States
(12) Patent Application Publication
(10) Pub. No.: US 2024/0351905 A1
(43) Pub. Date: Oct. 24, 2024

(54) SEMICONDUCTOR LAYER INCLUDING Sn BASED PEROVSKITE INCLUDING CHLORIDE-BASED COMPOUND AND IODIDE-BASED COMPOUND, THIN FILM TRANSISTOR INCLUDING SAME, AND MANUFACTURING METHOD THEREOF

(71) Applicant: POSTECH RESEARCH AND BUSINESS DEVELOPMENT FOUNDATION, Pohang-si (KR)

(72) Inventors: Yong-Young NOH, Pohang-si (KR); Youjin REO, Pohang-si (KR); Ao LIU, Pohang-si (KR); Huihui ZHU, Pohang-si (KR)

(21) Appl. No.: 18/586,784

(22) Filed: Feb. 26, 2024

(30) Foreign Application Priority Data
Apr. 24, 2023 (KR) 10-2023-0053519
Jan. 18, 2024 (KR) 10-2024-0008156

(51) Int. Cl. C01G 19/00; H01L 21/02; H01L 29/24; H01L 29/66; H01L 29/786; H10K 10/46; H10K 71/16

(52) U.S. Cl. CPC C01G 19/006; H01L 29/24; H01L 29/66969; H01L 29/786; H10K 10/484; C01P 2002/34; C01P 2002/52; C01P 2006/40; H01L 21/02521; H01L 21/02631; H10K 71/164

(57) ABSTRACT

Proposed are a semiconductor layer including Sn-based perovskite including a chloride-based compound and an iodine-based compound, a thin film transistor including the same, and a manufacturing method thereof. The semiconductor layer includes a perovskite complex, where the perovskite complex includes a Sn-based perovskite and an additive including at least one selected from the group consisting of a first additive and a second additive, the first additive includes at least one selected from the group consisting of a chloride-based compound and an acetate-based compound, and the second additive includes an iodide-based compound (iodide). Thus, a transistor, an environmentally friendly material free of Pb, having high charge mobility and being easily industrialized, can be provided.

### CROSS REFERENCE TO RELATED APPLICATION

The present application claims priority to Korean Patent Application No. 10-2023-0053519, filed Apr. 24, 2023 and Korean Patent Application No. 10-2024-0008156, filed Jan. 18, 2024, the entire contents of which is incorporated herein for all purposes by this reference.

### BACKGROUND OF THE DISCLOSURE

### 1. Field of the Disclosure

The present disclosure relates to a semiconductor layer including a Sn-based perovskite including a chloride-based compound and an iodide-based compound, a thin film transistor including the same, and a manufacturing method thereof.

### 2. Description of the Related Art

The research on hybrid organic-inorganic or inorganic perovskite materials as light absorbers for solar cells is actively taken place due to their high performance. Additionally, halide perovskites are expected to have high hole charge mobility due to the low effective mass of holes and thus have great potential as p-type transistors. Furthermore, electrical properties are adjustable with combinations of cations and anions because various materials can be applied to cations and anions in halide-based perovskites, thus providing customized electronic materials for a wide range of applications. However, there are obstacles in their commercialization because such high performance is only shown in materials using lead (Pb) as a cation, which is harmful to the human body. Therefore, it is an important task to develop high optoelectronic properties using Pb-free halide perovskite materials.

Of all Pb-free halide perovskite materials, tin (Sn) as a cation for perovskite materials are actively studied. Sn is less harmful to the human body and the environment than Pb. Additionally, Sn has electrical properties analogous to those of Pb and thus is expected to show high optoelectronic device performance. However, Sn is easily oxidized from Sn²⁺ to Sn⁴⁺ by oxygen in the air and loses the excellent electrical properties thereof, which is problematic. Thus, there is a need for technology to prevent oxidation.

Additionally, when forming Sn-based perovskite thin films, Sn vacancies have low formation energy, and a large number thereof thus is likely to be generated. Such Sn vacancies mainly create a shallow trap states near the valence band maximum (VBM), thereby increasing the number of holes. Accordingly, typically formed Sn-based perovskite thin films exhibit the characteristics of conductive thin films due to having a high hole concentration of about 10¹⁸ /cm³, making it challenging to be applied to semiconductor thin films.

As a result, to apply Sn-based perovskite thin films as semiconductor thin films for transistors, solar cells, light-emitting devices, light-receiving devices, and the like, technology to minimize the generation of Sn vacancies generated during the thin film formation process or to reduce the number of Sn vacancies generated is required to be developed.

### SUMMARY OF THE INVENTION

The present disclosure aims to provide a semiconductor layer including a Sn-based perovskite complex and a manufacturing method thereof by forming a Sn-based halide perovskite thin film through a thermal evaporation process.

Additionally, the present disclosure aims to provide a p-type thin film transistor having high hole charge mobility and stability by using a semiconductor layer including a Sn-based perovskite complex as an active layer.

Furthermore, the present disclosure aims to provide a thin film transistor that is easily industrialized by including a Pb-free semiconductor layer using Sn, an environmentally friendly material, as a cation.

According to one aspect of the present disclosure, provided is a semiconductor layer including a perovskite complex, where the perovskite complex includes a Sn-based perovskite and an additive including at least one selected from the group consisting of a first additive and a second additive, the first additive includes at least one selected from the group consisting of a chloride-based compound and an acetate-based compound, and the second additive includes an iodide-based compound.

Additionally, the Sn-based perovskite may include grains and a grain boundary formed between the grains that are adjacent to each other, and the at least one selected from the group consisting of the first and second additives may be positioned on the grain boundary.

Additionally, the Sn-based perovskite may be doped with the at least one selected from the group consisting of the first and second additives.

Additionally, the Sn-based perovskite may include grains and a grain boundary formed between the grains that are adjacent to each other, the Sn-based perovskite may be doped with the first additive, and the second additive may be positioned on the grain boundary.

The perovskite complex may include 0.1 to 50 mol of the additive based on 100 mol of Sn in the Sn-based perovskite.

Additionally, the chloride-based compound may include at least one selected from the group consisting of PbCl₂, SnCl₂, CsCl, formamidinium chloride (FACl), methylammonium chloride (MACl), and phenylethylammonium chloride (PEACl).

Additionally, the acetate-based compound may include at least one selected from the group consisting of lead(II) acetate (PbAc₂), tin(II) acetate (SnAc₂), cesium acetate (CsAc), formamidinium acetate (FAAc), methylammonium acetate (MAAc), and phenylethylammonium acetate (PEAAc).

Additionally, the iodide-based compound may include at least one selected from the group consisting of RbI, KI, NaI, and LiI.

Additionally, a molar ratio (mₐ:m_{b}, mol:mol) of the first additive (a) to the second additive (b) may be in a range of 10:90 to 90:10.

Additionally, the Sn-based perovskite may be represented by Structural Formula 1 below.

A₍₁₋ₐ₎(B_{(1-b)}C_{b})ₐSn(X_{(1-c)}Y)₃ [Structural Formula 1]

In Structural Formula 1, A is cesium (Cs), B and C are different and each independently methylammonium (MA) or formamidinium (FA), a is a real number of 0≤a≤1, b is a real number of 0≤b≤1, X and Y are different and each independently fluorine (F), chlorine (Cl), bromine (Br), or iodine (I), and c is a real number of 0≤c≤1.

Additionally, the Sn-based perovskite may include at least one selected from the group consisting of cesium tin triiodide (CsSnI₃), methylammonium tin triiodide (MASnI₃), formamidinium tin triiodide (FASnI₃), and cesium formamidinium tin triiodide (CsFASnI₃).

Additionally, the perovskite complex may be applied to a semiconductor layer of at least one selected from the group consisting of a transistor, a solar cell, a light-emitting diode, a photodiode, and a photosensor.

Additionally, the semiconductor layer may have a thickness in a range of 1 to 100 nm.

According to another aspect of the present disclosure, provided is a perovskite thin film transistor. The transistor includes a gate electrode 100, an insulating layer 200 positioned on the gate electrode, a semiconductor layer 300 positioned on the insulating layer, the semiconductor layer including a perovskite complex, and a source electrode 400 and a drain electrode 500 spaced from each other while being positioned on the semiconductor layer, where the perovskite complex includes a Sn-based perovskite and an additive including at least one selected from the group consisting of a first additive and a second additive, the first additive includes at least one selected from the group consisting of a chloride-based compound and an acetate-based compound, and the second additive includes an iodide-based compound.

According to a further aspect of the present disclosure, provided is a method of manufacturing a semiconductor layer. The method includes (a) providing a Sn-based perovskite precursor and an additive including at least one selected from the group consisting of a first additive and a second additive, (b) coating a substrate with the Sn-based perovskite precursor and the additive including the at least one selected from the group consisting of the first and second additives, and (c) subjecting the resulting product of (b) to heat treatment to form a semiconductor layer including a perovskite complex, where the perovskite complex includes a Sn-based perovskite and the additive including the at least one selected from the group consisting of the first and second additives, the first additive includes at least one selected from the group consisting of a chloride-based compound and an acetate-based compound, and the second additive includes an iodide-based compound.

Additionally, the perovskite complex may include 0.1 to 50 mol of the additive based on 100 mol of Sn in the Sn-based perovskite.

Additionally, the perovskite complex may include the Sn-based perovskite and the additive.

Additionally, the heat treatment may be performed at a temperature in a range of room temperature to 330° C.

Additionally, (b) may be performed by at least one method selected from the group consisting of thermal evaporation, chemical vapor deposition (CVD), atomic layer deposition (ALD), sputtering, spin coating, bar coating, slot coating, dip coating, spray coating, gravure coating, inkjet coating, dispensing coating, flexography, screen coating, and a combination thereof.

Additionally, (b) may be performed by thermal evaporation.

Additionally, the thermal evaporation may be performed under a pressure in a range of 0 to 10⁻³ Torr, which is preferably in the range of 0 to 10⁻⁷ Torr.

Additionally, (b) may include (b-1) coating the substrate with the Sn-based perovskite precursor and (b-2) coating the substrate with the first additive, and (b-1) and (b-2) may be performed simultaneously or separately.

Additionally, (b) may further include (b-3) coating the substrate with the second additive, and (b-1), (b-2), and (b-3) may be performed simultaneously or separately.

A thin film transistor of the present disclosure is an environmentally friendly material free of Pb and thus can be easily industrialized.

Additionally, an additive including at least one selected from the group consisting of a chloride-based compound and an acetate-based compound is added to the thin film transistor of the present disclosure, enabling control of hole concentration and improvement of crystallinity and effectively reducing the quantity of electric charge. As a result, a transistor with a low off-state current can be provided.

Additionally, an iodide-based additive is added to strengthen bond strength by fine reduction of a crystal structure, thus improving the stability of a lattice structure and the crystallinity of a thin film. As a result, a transistor with high charge mobility can be provided.

### BRIEF DESCRIPTION OF THE DRAWINGS

These drawings are for the purpose of describing exemplary embodiments of the present disclosure, and therefore the technical idea of the present disclosure should not be construed as being limited to the accompanying drawings:

FIG. 1 is a schematic diagram illustrating a thin film transistor according to one example of the present disclosure;

FIG. 2 is a flowchart showing a method of manufacturing a semiconductor layer according to one example of the present disclosure;

FIG. 3 shows X-ray diffraction (XRD) analysis results of Comparative Example 1 and Examples 2-5 and 3-2;

FIG. 4 shows scanning electron microscope (SEM) analysis results of Comparative Example 1 and Examples 2-5 and 3-2;

FIG. 5 is a schematic diagram illustrating a thin film transistor manufactured according to Device Example 3;

FIG. 6 shows an output curve for Device Example 3-2;

FIG. 7 shows a transfer curve for Device Example 3-2;

FIG. 8 shows a transfer curve for Device Comparative Example 1 and Device Examples 1-1 to 1-3;

FIG. 9 shows a transfer curve for Device Examples 2-1 to 2-6;

FIG. 10 shows a transfer curve for Device Examples 3-1 to 3-4;

FIG. 11 shows a transfer curve for Device Comparative Example 1 and Device Examples 2-5 and 3-2; and

FIG. 12 shows a transfer curve for Device Examples 1-2, 4, and 1-1.

### DESCRIPTION OF THE PREFERRED EMBODIMENTS

Hereinafter, embodiments of the present disclosure will be described in detail with reference to the accompanying drawings so that those skilled in the art can easily carry out the present disclosure.

However, the following description does not limit the present disclosure to specific embodiments. In the following description of the present disclosure, the detailed description of related arts will be omitted if it is determined that the gist of the present disclosure may be blurred.

Terms used herein are used only to describe specific embodiments and are not intended to limit the present disclosure. The singular expression includes the plural expression unless the context clearly indicates otherwise. It will be further understood that the terms “comprises”, “includes”, or “has” when used herein specify the presence of stated features, regions, integers, steps, operations, elements, and/or components, but do not preclude the presence or addition of one or more other features, regions, integers, steps, operations, elements, components, and/or combinations thereof.

Additionally, terms, such as “first”, “second”, etc. used herein, may be used to describe various components, but the components are not to be construed as being limited to the terms. These terms are used only for the purpose of distinguishing a component from another component. For example, without departing from the scope of the present disclosure, a first component may be referred to as a second component, and a second component may be also referred to as a first component.

Additionally, when a component is referred to as being “formed” or “stacked” on another component, it may be formed directly or attached to the front or one surface on the surface of the other component, but it will be understood that intervening elements may be present therebetween.

Hereinafter, a semiconductor layer including a Sn-based perovskite, a thin film transistor including the same, and a manufacturing method thereof will be described in detail. However, these are disclosed only for illustrative purposes and are not meant to limit the present disclosure, and the scope of the present disclosure is only defined by the appended claims.

The present disclosure provides a semiconductor layer including a perovskite complex, where the perovskite complex includes a Sn-based perovskite and an additive including at least one selected from the group consisting of a first additive and a second additive, the first additive includes at least one selected from the group consisting of a chloride-based compound and an acetate-based compound, and the second additive includes an iodide-based compound.

Additionally, the Sn-based perovskite may include grains and a grain boundary formed between the grains that are adjacent to each other, and the at least one selected from the group consisting of the first and second additives may be positioned on the grain boundary.

Additionally, the Sn-based perovskite may be doped with the at least one selected from the group consisting of the first and second additives.

Additionally, the Sn-based perovskite may include grains and a grain boundary formed between the grains that are adjacent to each other, the Sn-based perovskite may be doped with the first additive, and the second additive may be positioned on the grain boundary.

The perovskite complex may include 0.1 to 50 mol of the additive, which is preferably in the range of 1 to 30 mol, based on 100 mol of Sn in the Sn-based perovskite. When the perovskite complex includes less than 0.1 mol of the additive based on 100 mol of Sn in the Sn-based perovskite, the effect of reducing the quantity of electric charge is insignificant. Thus, there may be problems in that the off-current is still high, and the on/off current ratio is low, which is undesirable. On the contrary, when the perovskite complex includes more than 50 mol of the additive based on 100 mol of Sn in the Sn-based perovskite, there may be a problem in that agglomeration of the additives may rather lead to a decrease in charge mobility, which is undesirable.

Additionally, the chloride-based compound may include at least one selected from the group consisting of PbCl₂, SnCl₂, CsCl, formamidinium chloride (FACl), methylammonium chloride (MACl), and phenylethylammonium chloride (PEACl).

Additionally, the acetate-based compound may include at least one selected from the group consisting of lead(II) acetate (PbAc₂), tin(II) acetate (SnAc₂), cesium acetate (CsAc), formamidinium acetate (FAAc), methylammonium acetate (MAAc), and phenylethylammonium acetate (PEAAc).

In this case, Pb added to the first additive may be contained in a trace amount that is environmentally harmless.

Additionally, the iodide-based compound may include at least one selected from the group consisting of RbI, KI, NaI, and LiI.

In this case, the first additive may serve to control defects and hole concentration through the introduction of Cl or Ac. Additionally, in the second additive, Rb, K, Na, or Li is replaced with Cs to reduce the lattice volume, increase bond strength, and improve the stability of a lattice structure, thereby improving the crystallinity of a thin film.

Accordingly, when the first and second additives are included, an optimal thin film may be formed through the control of defects and hole concentration as well as the improvement of crystallinity.

In this case, the chloride/acetate-based additives enable the control of hole concentration and the improvement of crystallinity through thermal evaporation during thin film formation. Additionally, the cation iodide-based additive may be added to strengthen bond strength by fine reduction of the crystal structure, leading to improvement in crystallinity and stability of the lattice structure.

Additionally, the additive may be PbCl₂, SnCl₂, CsCl, FACl, MACl, PEACl, PbAc₂, SnAc₂, CsAc, FAAc, MAAc, PEAAc, or may include at least one selected from the group consisting of PbCl₂:RbI, SnCl₂:RbI, CsCl:RbI, FACl:RbI, MACl:RbI, PEACl:RbI, PbAc₂:RbI, SnAc₂:RbI, CsAc:RbI, FAAc:RbI, MAAc:RbI, PEAAc:RbI, PbCl₂:KI, SnCl₂:KI, CsCl:KI, FACl:KI, MACl:KI, PEACl:KI, PbAc₂:KI, SnAc₂:KI, CsAc:KI, FAAc:KI, MAAc:KI, PEAAc:KI, PbCl₂:NaI, SnCl₂:NaI, CsCl:NaI, FACl:NaI, MACl:NaI, PEACl:NaI, PbAc₂:NaI, SnAc₂:NaI, CsAc:NaI, FAAc:NaI, MAAc:NaI, PEAAc:NaI, PbCl₂:LiI, SnCl₂:LiI, CsCl:LiI, FACl:LiI, MACl:LiI, PEACl:LiI, PbAc₂:LiI, SnAc₂:LiI, CsAc:LiI, FAAc:LiI, MAAc:LiI, and PEAAc:LiI.

Additionally, a molar ratio (mₐ:m_{b}, mol:mol) of the first additive (a) to the second additive (b) may be in a range of 10:90 to 90:10, which is preferably in the range of 20:80 to 80:20 and more preferably in the range of 30:70 to 70:30. When the molar ratio is lower than 10:90, the excessive amount of the cation iodide additive introduced may result in distortion of the crystal structure, which is undesirable. On the contrary, when the molar ratio exceeds 90:10, the effect of reducing the quantity of electric charge is more excessive than necessary, leading to decreases in both off-current and on-current and a deterioration in performance, which is undesirable.

Additionally, the Sn-based perovskite may be represented by Structural Formula 1 below.

A₍₁₋ₐ₎(B_{(1-b)}C_{b})ₐSn(X_{(1-c)}Y)₃ [Structural Formula 1]

In Structural Formula 1, A is cesium (Cs), B and C are different and each independently methylammonium (MA) or formamidinium (FA), a is a real number of 0≤a≤1, b is a real number of 0≤b≤1, X and Y are different and each independently fluorine (F), chlorine (Cl), bromine (Br), or iodine (I), and c is a real number of 0≤c≤1.

Additionally, the Sn-based perovskite may include at least one selected from the group consisting of cesium tin triiodide (CsSnI₃), methylammonium tin triiodide (MASnI₃), formamidinium tin triiodide (FASnI₃), and cesium formamidinium tin triiodide (CsFASnI₃).

Additionally, the perovskite complex may be applied to a semiconductor layer of at least one selected from the group consisting of a transistor, a solar cell, a light-emitting diode, a photodiode, and a photosensor.

Additionally, the semiconductor layer may have a thickness in a range of 1 to 100 nm, which is preferably in the range of 3 to 50 nm. When the thickness of the semiconductor layer is smaller than 1 nm, deposition on the entire surface of the substrate may be challenging, which is undesirable. On the contrary, when the thickness of the semiconductor layer exceeds 100 nm, an excessive quantity of electric charge may be retained, which is undesirable. As the structure having such an extremely small thickness is formed, implementation in flexible applications is possible, and the semiconductor layer may be used in transistors, p-n junctions, diodes, and the like, but is not limited thereto.

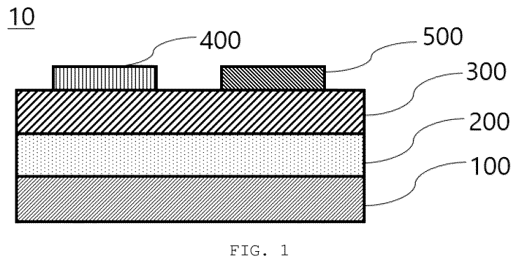

FIG. 1 is a schematic diagram illustrating a thin film transistor according to one example of the present disclosure.

Referring to FIG. 1, the present disclosure provides a perovskite thin film transistor 10. The perovskite thin film transistor includes a gate electrode 100, an insulating layer 200 positioned on the gate electrode, a semiconductor layer 300 positioned on the insulating layer, the semiconductor layer including a perovskite complex, and a source electrode 400 and a drain electrode 500 spaced from each other while being positioned on the semiconductor layer, where the perovskite complex includes a Sn-based perovskite and an additive including at least one selected from the group consisting of a first additive and a second additive, the first additive includes at least one selected from the group consisting of a chloride-based compound and an acetate-based compound, and the second additive includes an iodide-based compound.

In this case, the thin film transistor of the present disclosure may further include a substrate or a substrate including the gate electrode, as needed. The thin film transistor 10 is described in terms of a bottom-gate top-contact (BGTC) structure, but is not limited thereto, and may also be applied to a bottom-gate bottom-contact (BGBC) structure, and the like, but is not limited thereto. A bottom-type thin film transistor is configured by the following steps: providing a substrate, forming a gate electrode on the substrate, forming an insulating layer on the gate electrode, forming a semiconductor layer on the insulating layer, and forming a source electrode and drain electrode spaced from each other while being positioned on the organic semiconductor layer.

Additionally, the substrate may include a p-doped or n-doped silicon wafer, a glass substrate, a plastic film including at least one selected from the group consisting of polyethersulfone, polyacrylate, polyether imide, polyimide, polyethylene terephthalate, and polyethylene naphthalate, a glass substrate coated with indium tin oxide, and a plastic film.

Additionally, the gate electrode 100 may be formed by including at least one selected from the group consisting of aluminum (Al), gold (Au), silver (Ag), an aluminum alloy (Al-alloy), molybdenum (Mo), a molybdenum alloy (Mo-alloy), silver nanowires, gallium indium eutectic, n-doped silicon (n-doped Si), p-doped silicon (p-doped Si), platinum (Pt), titanium (Ti), tungsten (W), Magnesium (Mg), calcium (Ca), ytterbium (Yb), chromium (Cr), nickel (Ni), gold oxide, platinum oxide, silver oxide, palladium oxide, iron oxide, graphene, carbon nanotubes (CNTs), indium tin oxide, and poly(3,4-ethylenedioxythiophene) polystyrene sulfonate (PEDOT:PSS). The gate electrode 100 may be manufactured through a printing process such as inkjet printing or spraying using the materials mentioned above as ink. Such printing processes of the gate electrode 100 exclude a vacuum process, so reducing manufacturing costs may be expected.

Additionally, the insulating layer 200 may be formed on the entire surface of the gate electrode 100. Additionally, the insulating layer 200 may be formed on the entire surface of the substrate including the gate electrode 100. The insulating layer 200 may be included in the form of a single layer or multilayer of an organic or inorganic insulating film or may be included in the form of an organic-inorganic hybrid film. The organic insulating film used may include at least one selected from the group consisting of polymethyl methacrylate (PMMA), polystyrene (PS), polyethylene naphthalate (PEN), polyethylene terephthalate (PET), polyvinyl chloride (PVC), polyvinylpyrrolidone (PVP), polyethylene (PE), a phenol-based polymer, an acrylic polymer, an imide-based polymer such as polyimide, an aryl ether-based polymer, an amide-based polymer, a fluorine-based polymer, a p-xylylene-based polymer, a vinyl alcohol-based polymer, and parylene. The inorganic insulating film used may include at least one selected from the group consisting of a silicon oxide film, a silicon nitride film, alumina (Al₂O₃), hafnium oxide (HfO₂), tantalum oxide (Ta₂O₅), zirconium oxide (ZrO₂), barium strontium titanate (BST), Pb(Zr,Ti)O₃ (PZT), glass, quartz, silicon carbide, magnesium oxide, and germanium.

Additionally, the semiconductor layer 300 may be formed on the entire surface of the insulating layer 200. The semiconductor layer 300 having an ultra-thin structure may be formed on the insulating layer 200 using a method including at least one selected from the group consisting of thermal evaporation, a solution process (spin coating, bar coating, slot coating, inkjet coating, dispensing, spray coating, and the like), a mixing process (two-step process: a solution process after vacuum deposition), flexography, screen coating, dip coating, chemical vapor deposition (CVD), atomic layer deposition (ALD), sputtering, and gravure coating, which preferably includes thermal evaporation, spin coating, or bar coating, and is more preferably thermal evaporation.

In this case, when the substrate is included, the temperature of the substrate during the thermal evaporation process may be in a range of room temperature to 300° C. The thermal evaporation process is advantageous in that the thickness of the thin film is adjustable to a desired value and is reproducibly obtainable without depending on operators.

Additionally, after forming the semiconductor layer 300, heat treatment or optical exposure may be further performed to improve device performance such as stability and crystallinity of the semiconductor.

Additionally, the source electrode 400 and the drain electrode 500 may be formed as a single layer by including at least one selected from the group consisting of Au, Ag, Pt, Al, W, Mg, Ca, Yb, Mo or an alloy thereof, Cs-ITO, gold oxide, platinum oxide, silver oxide, palladium oxide, iron oxide, and indium tin oxide.

Additionally, in the case where the substrate is included, a multilayer may be formed by further including an adhesive metal layer, such as Ti, Cr, or Ni, to improve adhesion to the substrate. Additionally, devices that are more flexible in elasticity than existing metals may be manufactured using graphene, carbon nanotubes (CNTs), PEDOT:PSS conductive polymer silver nanowires, and the like. Using these materials as ink, the source electrode and the drain electrode may be manufactured through a printing process such as inkjet printing or spraying. Such a printing process enables the source electrode and the drain electrode to be formed, excluding a vacuum process, so the effect of reducing manufacturing costs may be expected.

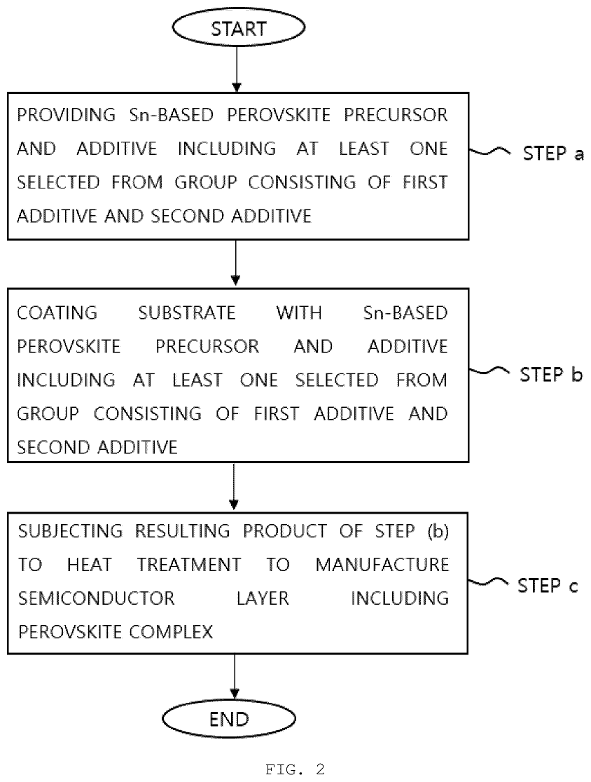

FIG. 2 is a flowchart showing a method of manufacturing the semiconductor layer according to one example of the present disclosure. Referring to FIG. 2, the present disclosure provides a method of manufacturing a semiconductor layer. The method includes (a) providing a Sn-based perovskite precursor and an additive including at least one selected from the group consisting of a first additive and a second additive, (b) coating a substrate with the Sn-based perovskite precursor and the additive including the at least one selected from the group consisting of the first and second additives, and (c) subjecting the resulting product of (b) to heat treatment to manufacture a semiconductor layer including a perovskite complex, where the perovskite complex includes a Sn-based perovskite and the additive including the at least one selected from the group consisting of the first and second additives, the first additive includes at least one selected from the group consisting of a chloride-based compound and an acetate-based compound, and the second additive includes an iodide-based compound.

Additionally, the perovskite complex may include 0.1 to 50 mol of the additive, which is preferably in the range of 1 to 30 mol, based on 100 mol of Sn in the Sn-based perovskite. When the perovskite complex includes less than 0.1 mol of the additive based on 100 mol of Sn in the Sn-based perovskite, the effect of reducing the quantity of electric charge is insignificant. Thus, there may be problems in that the off-current is still high, and the on/off current ratio is low, which is undesirable. On the contrary, when the perovskite complex includes more than 50 mol of the additive based on 100 mol of Sn in the Sn-based perovskite, there may be a problem in that agglomeration of the additives may rather lead to a decrease in charge mobility, which is undesirable.

Additionally, the thermal annealing treatment may be performed at a temperature in a range of room temperature to 330° C., which is preferably in the range of 100° C. to 320° C. and more preferably in the range of 200° C. to 310° C. In this case, when the thermal annealing treatment is performed at a temperature below room temperature, thermal energy may be insufficient to cause a reaction between the deposited precursor and the additive, which is undesirable. On the contrary, when the heat treatment is performed at a temperature above 330° C., excessive thermal energy may result in damage to the crystal structure of perovskite, which is undesirable. The thermal annealing treatment may refer to annealing, meaning that an object receives thermal energy by keeping the object at a constant temperature.

Additionally, (b) may be performed by at least one method selected from the group consisting of thermal evaporation, chemical vapor deposition (CVD), atomic layer deposition (ALD), sputtering, spin coating, bar coating, slot coating, dip coating, spray coating, gravure coating, inkjet coating, dispensing coating, flexography, screen coating, and a combination thereof.

Additionally, (b) is preferably performed by thermal evaporation. Through the thermal evaporation process, the semiconductor layer having the ultra-thin structure may be formed on the insulating layer. The thermal evaporation process is advantageous in that the thickness of the thin film is adjustable to a desired value and is reproducibly obtainable without depending on operators.

Additionally, the thermal evaporation may be performed under a pressure in a range of 0 to 10⁻³ Torr, which is preferably in the range of 0 to 10⁻⁷ Torr. In this case, when the vacuum pressure is higher than 10⁻³ Torr, impurities may be contained, which is undesirable.

Additionally, in the thermal evaporation process, the deposition rate may be in a range of 0.01 to 100 Å/s. In this case, when the deposition rate is lower than 0.01 Å/s, the thin film deposition process may take an excessively long time, which is undesirable. On the contrary, when the deposition rate exceeds 100 Å/s, the surface roughness of the thin film increases, which is undesirable.

Additionally, (b) may include (b-1) coating the substrate with the Sn-based perovskite precursor and (b-2) coating the substrate with the first additive, and (b-1) and (b-2) may be performed simultaneously or separately.

Additionally, (b) may further include (b-3) coating the substrate with the second additive, and (b-1), (b-2), and (b-3) may be performed simultaneously or separately.

Additionally, after the thermal evaporation process in the thermal annealing treatment, the temperature of the substrate may be in a range of room temperature to 330° C., which is preferably in the range of 100° C. to 320° C. and more preferably in the range of 200° C. to 310° C. In this case, when the temperature of the substrate is below room temperature, thermal energy may be insufficient to cause a reaction between the deposited precursor and the additive, which is undesirable. On the contrary, when the temperature of the substrate exceeds 330° C., excessive thermal energy may result in damage to the crystal structure of perovskite, which is undesirable.

On the other hand, existing solution processes are problematic in that it is challenging to adjust the thickness of the thin film and reproducibly obtain thickness. However, in the present disclosure, the thickness of the thin film is reproducibly obtainable using the thermal evaporation process. Additionally, in the present disclosure, Sn is used instead of Pb, which is harmful to the human body, and the additive is used to prevent Sn oxidation and the generation of a large number of vacancies. As a result, the hole concentration is controlled, and the crystallinity is improved, thus providing the semiconductor layer in which the stability of the lattice structure is improved. Furthermore, the transistor, including the semiconductor layer, has high hole charge mobility and stability.

### EXAMPLE

Hereinafter, the present disclosure will be described in more detail with examples. However, these examples are disclosed for illustrative purposes and the scope of the present disclosure is not limited thereby.

### Manufacture of Semiconductor Layer

### Example 1: CsPbSnIₓCl₃₋ₓ with Varying Molar Ratio of PbCl₂

### Example 1-1: 10 Mol of PbCl₂ (Sequential Deposition)

FIG. 2 is a flowchart showing a method of manufacturing a semiconductor layer according to one example of the present disclosure. Referring to FIG. 2, for the deposition of a Sn-based semiconductor layer, CsI and SnI₂ precursors were used as deposition sources. As a result of using a thermal evaporation process in a vacuum chamber, a Sn-based perovskite was deposited in a thin film form on a silicon/silicon oxide (Si⁺⁺/SiO₂) substrate through vacuum deposition. Based on 100 mol of Sn in the Sn-based perovskite, 10 mol of a first additive, PbCl₂, was introduced into the perovskite using the thermal evaporation process. In this case, the temperature of the substrate was 25° C., the vacuum pressure before deposition was 10⁻⁷ Torr or less, and the deposition rate was 1 As⁻¹. The deposited sample was first subjected to heat treatment through annealing at 150° C. for 10 minutes in a glove box filled with N₂ to manufacture a semiconductor layer including the perovskite complex.

### Example 1-1′: 10 Mol of PbCl₂ (Co-Deposition)

FIG. 2 is a flowchart showing a method of manufacturing a semiconductor layer according to one example of the present disclosure. Referring to FIG. 2, for the deposition of a Sn-based semiconductor layer, CsI and SnI₂ precursors were used as deposition sources, and 10 mol of a first additive, PbCl₂, was used based on 100 mol of Sn in the Sn-based perovskite. As a result of using a thermal evaporation process in a vacuum chamber, a Sn-based perovskite complex was deposited in a thin film form on a silicon/silicon oxide (Si⁺⁺/SiO₂) substrate through vacuum deposition. In this case, the temperature of the substrate was 25° C., the vacuum pressure before deposition was 10⁻⁷ Torr or less, and the deposition rate was 1 As⁻¹. The deposited sample was first subjected to heat treatment through annealing at 150° C. for 10 minutes in a glove box filled with N₂ to manufacture a semiconductor layer including the perovskite complex.

### Example 1-2: 15 Mol of PbCl₂

A semiconductor layer was manufactured in the same manner as in Example 1-1, except that the first additive, PbCl₂, was introduced into the perovskite using the thermal evaporation process in an amount of 15 mol instead of 10 mol, based on 100 mol of Sn in the Sn-based perovskite.

### Example 1-3: 20 Mol of PbCl₂

A semiconductor layer was manufactured in the same manner as in Example 1-1, except that the first additive, PbCl₂, was introduced into the perovskite using the thermal evaporation process in an amount of 20 mol instead of 10 mol, based on 100 mol of Sn in the Sn-based perovskite.

### Example 2: CsPbSnIₓCl₃₋ₓ, 15 Mol of PbCl₂ with Varying Thermal Annealing Treatment Temperature

### Example 2-1: Room Temperature

A semiconductor layer was manufactured in the same manner as in Example 1-2, except that annealing was performed in the glove box at room temperature instead of 150° C.

### Example 2-2: 100° C.

A semiconductor layer was manufactured in the same manner as in Example 2-1, except that annealing was performed in the glove box at 100° C. instead of room temperature.

### Example 2-3: 150° C.

A semiconductor layer was manufactured in the same manner as in Example 2-1, except that annealing was performed in the glove box at 150° C. instead of room temperature.

### Example 2-4: 180° C.

A semiconductor layer was manufactured in the same manner as in Example 2-1, except that annealing was performed in the glove box at 180° C. instead of room temperature.

### Example 2-5: 300° C.

A semiconductor layer was manufactured in the same manner as in Example 2-1, except that annealing was performed in the glove box at 300° C. instead of room temperature.

### Example 2-6: 350° C.

A semiconductor layer was manufactured in the same manner as in Example 2-1, except that annealing was performed in the glove box at 350° C. instead of room temperature.

### Example 3: CsPbSnIₓCl₃₋ₓ:RbI, 15 Mol of PbCl₂ with Varying Content of Additional RbI

### Example 3-1: 8 Mol of RbI

A semiconductor layer was manufactured in the same manner as in Example 1-1, except that 15 mol of PbCl₂ and 8 mol of RbI were introduced into the perovskite using the thermal evaporation process instead of 10 mol of PbCl₂, based on 100 mol of Sn in the Sn-based perovskite, and annealing was performed in the glove box at 300° C. instead of 150° C.

### Example 3-2: 6 Mol of RbI

A semiconductor layer was manufactured in the same manner as in Example 3-1, except that RbI was introduced in an amount of 6 mol instead of 8 mol.

### Example 3-3: 4 Mol of RbI

A semiconductor layer was manufactured in the same manner as in Example 3-1, except that RbI was introduced in an amount of 4 mol instead of 8 mol.

### Example 3-4: 2 Mol of RbI

A semiconductor layer was manufactured in the same manner as in Example 3-1, except that RbI was introduced in an amount of 2 mol instead of 8 mol.

### Example 4: CsSnI₃:PbX₂, 10 Mol of PbCl₂ and 2 Mol of PbAc₂

A semiconductor layer was manufactured in the same manner as in Example 1-1, except that 10 mol of PbCl₂ and 2 mol of PbAc₂ were introduced into the perovskite using the thermal evaporation process instead of 10 mol of PbCl₂, based on 100 mol of Sn in the Sn-based perovskite.

### Comparative Example 1: CsSnI₃, 0 Mol of PbCl₂

A semiconductor layer was manufactured in the same manner as in Example 1-1, except that, instead of introducing 10 mol of PbCl₂ into the perovskite using the thermal evaporation process based on 100 mol of Sn in the Sn-based perovskite, PbCl₂ was not involved.

TABLE 1

| | Molar ratio | | | | |
|---|---|---|---|---|---|
| | | | | | Heat |
| | Sn-based | First additive | | Second | treatment |
| | perovskite | PbCl₂ | PbAc₂ | additive | temperature |
| Classification | (mol) | (mol) | (mol) | RbI (mol) | (° C.) |
| Example 1-1 | 100 | 10 | 0 | 0 | 150 |
| Example 1-2 | 100 | 15 | 0 | 0 | 150 |
| Example 1-3 | 100 | 20 | 0 | 0 | 150 |
| Example 2-1 | 100 | 15 | 0 | 0 | Room |
| | | | | | temperature |
| Example 2-2 | 100 | 15 | 0 | 0 | 100 |
| Example 2-3 | 100 | 15 | 0 | 0 | 150 |
| Example 2-4 | 100 | 15 | 0 | 0 | 180 |
| Example 2-5 | 100 | 15 | 0 | 0 | 300 |
| Example 2-6 | 100 | 15 | 0 | 0 | 350 |
| Example 3-1 | 100 | 15 | 0 | 8 | 300 |
| Example 3-2 | 100 | 15 | 0 | 6 | 300 |
| Example 3-3 | 100 | 15 | 0 | 4 | 300 |
| Example 3-4 | 100 | 15 | 0 | 2 | 300 |
| Example 4 | 100 | 10 | 2 | 0 | 150 |
| Comparative | 100 | 0 | 0 | 0 | 150 |
| Example 1 | | | | | |

### Manufacture of Thin Film Transistor

### Device Example 1

FIG. 1 is a schematic diagram illustrating a thin film transistor according to one example of the present disclosure, and FIG. 2 is a flowchart showing a method of manufacturing a semiconductor layer according to one example of the present disclosure.

Referring to FIGS. 1 and 2, for the deposition of a Sn-based semiconductor layer, CsI and SnI₂ precursors were used as deposition sources. As a result of using a thermal evaporation process in a vacuum chamber, the Sn-based perovskite was deposited in a thin film form on a silicon/silicon oxide (Si⁺⁺/SiO₂) substrate through vacuum deposition. Based on 100 mol of Sn in the Sn-based perovskite, 10 mol of a first additive, PbCl₂, was introduced into the perovskite using the thermal evaporation process. In this case, the temperature of the substrate was 25° C., the vacuum pressure before deposition was 10⁻⁷ Torr or less, and the deposition rate was 1 As⁻¹. The deposited sample was first subjected to heat treatment through annealing at 150° C. for 10 minutes in a glove box filled with N₂ to manufacture a semiconductor layer including the perovskite complex. The thickness of the Sn-based semiconductor layer was monitored during deposition, and the thin film was deposited to a thickness in a range of 3 to 50 nm. Next, a source electrode and a drain electrode were deposited using Au, thereby completing the manufacture of thin film transistor.

### Device Examples 2, 3, and 4 and Device Comparative Example 1

FIG. 1 is a schematic diagram illustrating a thin film transistor according to one example of the present disclosure, and FIG. 2 is a flowchart showing a method of manufacturing a semiconductor layer according to one example of the present disclosure.

Referring to FIGS. 1 and 2, transistors of Device Examples 2 to 4 and Device Comparative Example 1 were manufactured under the same conditions as in Device Example 1, except for varying the amount of additives used, type of additive, and deposition conditions. The manufacturing conditions are listed in Table 2 below.

TABLE 2

| Classification | Perovskite complex |
|---|---|
| Device Example 1-1 | Example 1-1 |
| Device Example 1-2 | Example 1-2 |
| Device Example 1-3 | Example 1-3 |
| Device Example 2-1 | Example 2-1 |
| Device Example 2-2 | Example 2-2 |
| Device Example 2-3 | Example 2-3 |
| Device Example 2-4 | Example 2-4 |
| Device Example 2-5 | Example 2-5 |
| Device Example 2-6 | Example 2-6 |
| Device Example 3-1 | Example 3-1 |
| Device Example 3-2 | Example 3-2 |
| Device Example 3-3 | Example 3-3 |
| Device Example 3-4 | Example 3-4 |
| Device Example 4 | Example 4 |
| Device Comparative Example 1 | Comparative Example 1 |

### TEST EXAMPLE

### Test Example 1: Comparison of Effects in the Presence or Absence of Additive

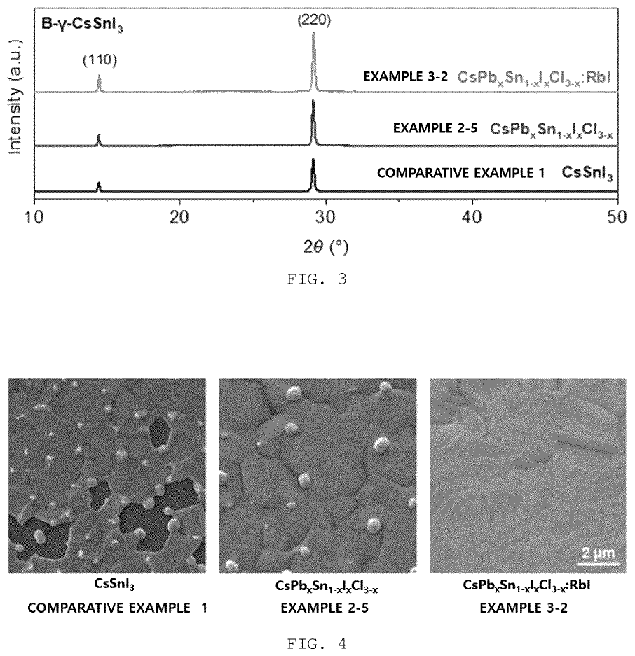

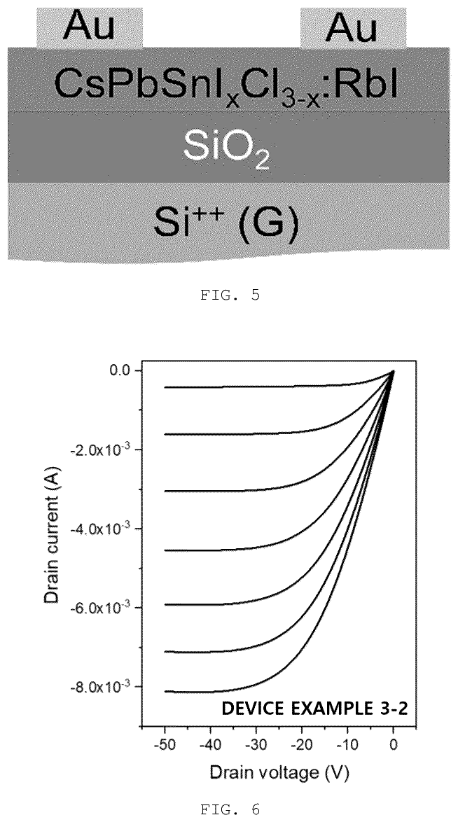

FIGS. 3 and 4 show X-ray diffraction (XRD) and scanning electron microscope (SEM) analysis results of Comparative Example 1 and Examples 2-5 and 3-2.

From FIGS. 3 and 4, it was confirmed through the XRD analysis results and SEM images that the introduction of the PbCl₂ additive into the perovskite semiconductor layer CsSnI₃ improved the crystalline phase of B-γ-CsSnI₃, and the introduction of PbCl₂ and RbI further improved crystallinity. In other words, it was confirmed even though the introduction of the PbCl₂ additive improved the crystalline phase, the introduction of the PbCl₂ and RbI additives further improved the crystallinity.

### Test Example 2: Confirmation of Characteristics of CsPbSnIₓCl₃₋ₓ: RbI Transistor

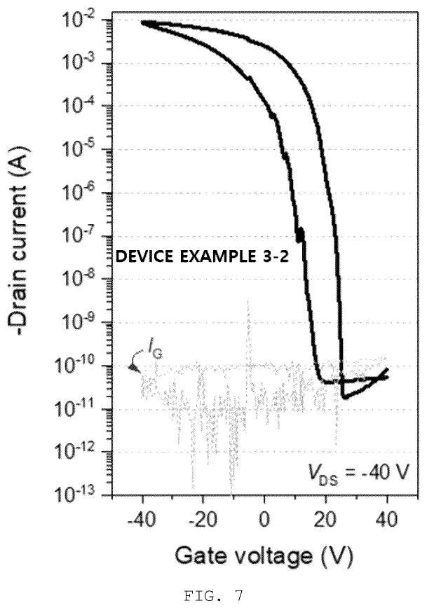

FIG. 5 is a schematic diagram illustrating the thin film transistor manufactured according to Device Example 3, and FIG. 6 shows an output curve for Device Example 3-2. FIG. 7 shows a transfer curve for Device Example 3-2. Specifically, FIG. 7 shows the current (I) flowing through the semiconductor layer including CsSnI₃ with the application of the gate voltage (VG). In this case, the voltage level between the source electrode and the drain electrode was set to −40 V (Vds=−40 V).

From FIGS. 6 and 7, it was confirmed that the thin film transistor, according to one example of the present disclosure, exhibited typical characteristics of p-type transistors. In this case, the level of field-effect mobility of holes was extremely high at about 50 to 60 cm²/VS, and the on/off current ratio was 10⁸ or higher, thus exhibiting excellent output/transmission characteristics and excellent electrical performance. In this case, when manufacturing the semiconductor layer, like in the case where the SnI₂ precursor and the PbCl₂ additive were deposited first, and then the CsI precursor and the RbI additive were deposited, the same results as shown in FIGS. 6 and 7 were confirmed in the case where the CsI and SnI₂ precursors and the PbCl₂ and RbI additives were introduced through co-deposition.

### Test Example 3: Confirmation of Characteristics of CsPbSnIₓCl₃₋ₓ Transistor with Varying Molar Ratio of PbCl₂

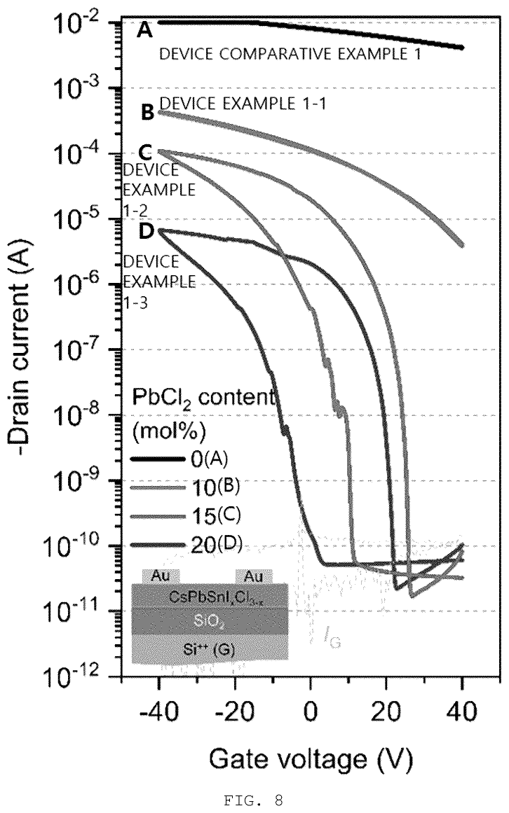

FIG. 8 shows a transfer curve for Device Comparative Example 1 and Device Examples 1-1 to 1-3. Referring to FIG. 8, in the case of Device Examples 1-1, 1-2, and 1-3 including the semiconductor layers into which 10, 15, and 20 mol of PbCl₂ were introduced, respectively, the introduction of PbCl₂ led to a gradual decrease in off-current, confirming that the off-current operation of the transistor was enabled to be performed. However, in the case of Device Comparative Example 1 (0 mol of additives), the on/off ratio appeared to be extremely low, confirming that the transistor failed to turn on and off. Additionally, it was confirmed that the CsSnI₃ thin film transistor free of additives functioned as a conductor with the generation of Sn vacancies during thin film formation. As a result, like Device Example 1-2 (including 15 mol of PbCl₂), it was confirmed to be most preferable to properly adjust the appropriate amount of additives added.

### Test Example 4: Confirmation of Characteristics of CsPbSnIₓCl₃₋ₓ Transistor with Varying Thermal Annealing Treatment Temperature

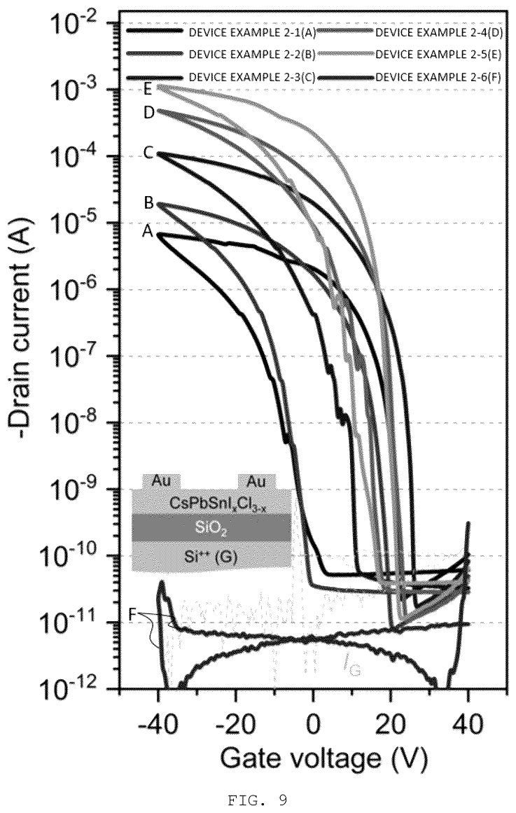

FIG. 9 shows a transfer curve for Device Examples 2-1 to 2-6, where the thermal annealing treatment after deposition is performed by varying temperatures at room temperature (RT), 100° C., 150° C., 180° C., 300° C., and 350° C.

Referring to FIG. 9, the higher the thermal annealing treatment temperature, the more the on-current. Thus, it is preferable to perform the thermal annealing treatment at high temperatures, like in the case of Device Example 2-5, in which the thermal annealing treatment was performed at 300° C. However, it was confirmed that at 350° C., a temperature exceeding 330° C., excessive thermal energy resulted in damage to the crystal structure of perovskite, which was undesirable.

### Test Example 5: Confirmation of Characteristics of CsPbSnIₓCl₃₋ₓ:RbI Transistor with Varying Molar Ratio of RbI

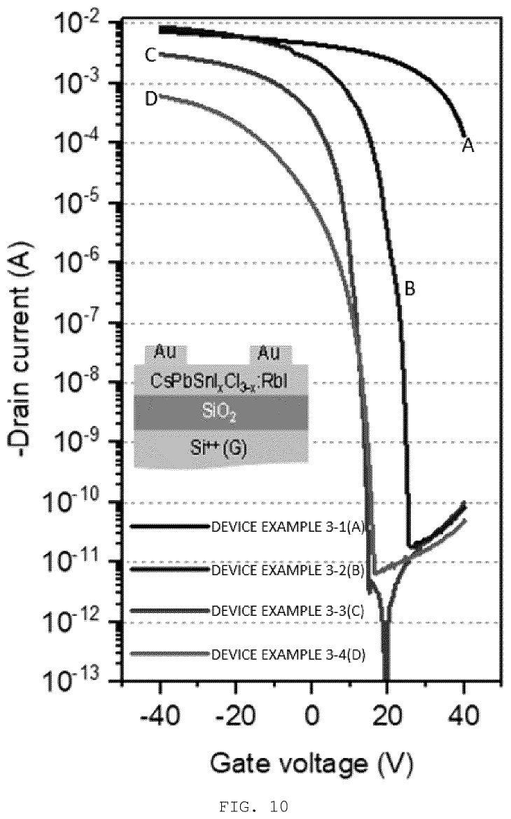

FIG. 10 shows a transfer curve for Device Examples 3-1 to 3-4. Specifically, FIG. 10 shows the transfer curve in the case of introducing 8, 6, 4, and 2 mol of RbI into 15 mol of PbCl₂. Referring to FIG. 10, in the case of Device Example 3-1 (including 15 mol of PbCl₂ and 8 mol of RbI), although the excessive amount of RbI added led to an increase in on-current, the off-current also increased. However, in the case of Device Example 3-2 (including 15 mol of PbCl₂ and 6 mol of RbI), in which the amount of RbI was reduced to 6 mol, the off-current gradually decreased while maintaining the high on-current, making it possible to perform the off-current operation of transistors. Additionally, a high on/off ratio was exhibited. In the case of Device Example 3-3 (including 15 mol of PbCl₂ and 4 mol of RbI) and Device Example 3-4 (including 15 mol of PbCl₂ and 2 mol of RbI), in which the amount of RbI added was insufficient, it was confirmed that the on-current was insufficiently high, which is undesirable. According to FIG. 10, it is seen that a transistor showing the best performance is obtainable when the molar ratio (mₐ:m_{b}, mol:mol) of PbCl₂ (the first additive) to RbI (the second additive) is 15:6.

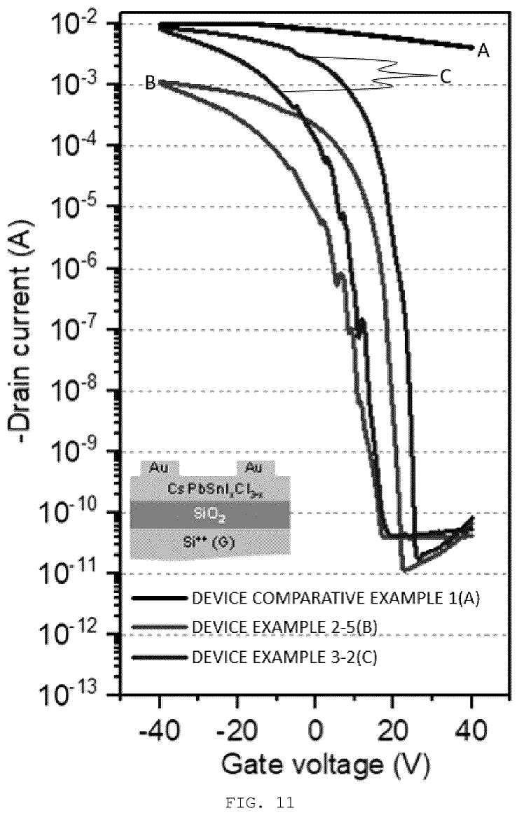

FIG. 11 shows a transfer curve for Device Comparative Example 1 and Device Examples 2-5 and 3-2. From FIG. 11, it was confirmed that Device Example 2-5 (including 15 mol of PbCl₂) exhibited a hole mobility of 5.55 cm²/Vs and an on/off ratio of 10⁸, and Device Example 3-2 (including 15 mol of PbCl₂ and 6 mol of RbI) exhibited a hole mobility of 58.4 cm²/Vs and an on/off ratio of 10⁸. However, in the case of Device Comparative Example 1 (0 mol of additives), the off-current was extremely high, confirming that the transistor failed to operate as a transistor and was only operated as a conductor. This confirmed that the off-current failed to be produced because the carrier concentration of CsSnI₃ was extremely high.

According to FIG. 11, it is seen that a thin film transistor showing the best performance while being capable of turning on/off is obtainable when introducing PbCl₂ and RbI because the number of Sn vacancies is reduced.

### Test Example 6: Confirmation of Characteristics of CsSnI₃:PbX₂ Transistor Including 10 Mol of PbCl₂ and 2 Mol of PbAc₂

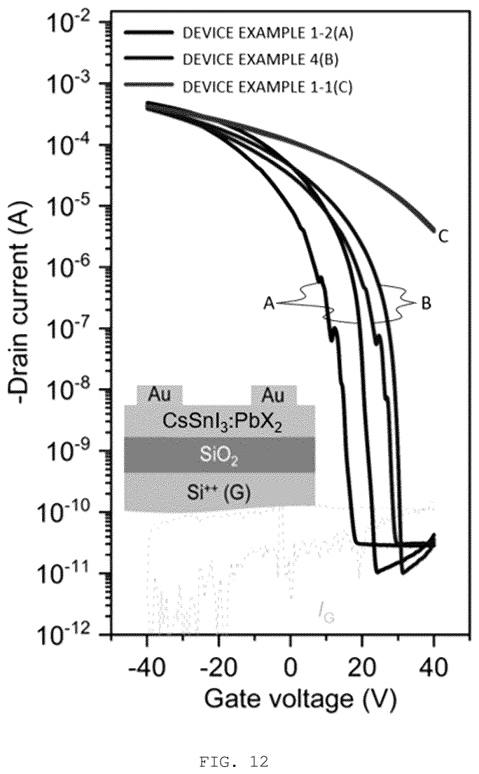

FIG. 12 shows a transfer curve for Device Examples 1-1, 1-2, and 4. Specifically, FIG. 12 shows the transition curve for the case where the CsSnI₃ semiconductor layer includes PbCl₂ or PbCl₂/PbAc₂. From FIG. 12, it was confirmed that Device Example 4 (including 10 mol of PbCl₂ and 2 mol of PbAc₂) exhibited an increased on/off ratio and a low off-current similar to that in the case of Device Example 1-2 (including 15 mol of PbCl₂). Thus, it was confirmed that when including a chloride-based compound and an acetate-based compound, the hole concentration of the perovskite semiconductor layer CsSnI₃ was adjustable.

The scope of the present disclosure is defined by the appended claims rather than the detailed description presented above. All changes or modifications derived from the meaning and scope of the claims and the concept of equivalents should be construed to fall within the scope of the present disclosure.

What is claimed is:

1. A semiconductor layer comprising a perovskite complex, wherein the perovskite complex comprises:
a Sn-based perovskite; and
an additive comprising at least one selected from the group consisting of a first additive and a second additive,
the first additive comprises at least one selected from the group consisting of a chloride-based compound and an acetate-based compound, and
the second additive comprises an iodide-based compound.

2. The semiconductor layer of claim 1, wherein the Sn-based perovskite comprises grains and a grain boundary formed between the grains that are adjacent to each other, and
the at least one selected from the group consisting of the first and second additives is positioned on the grain boundary.

3. The semiconductor layer of claim 1, wherein the Sn-based perovskite is doped with the at least one selected from the group consisting of the first and second additives.

4. The semiconductor layer of claim 1, wherein the perovskite complex comprises 0.1 to 50 mol of the additive based on 100 mol of Sn in the Sn-based perovskite.

5. The semiconductor layer of claim 1, wherein the chloride-based compound comprises at least one selected from the group consisting of PbCl₂, SnCl₂, CsCl, formamidinium chloride (FACl), methylammonium chloride (MACl), and phenylethylammonium chloride (PEACl).

6. The semiconductor layer of claim 1, wherein the acetate-based compound comprises at least one selected from the group consisting of lead(II) acetate (PbAc₂), tin(II) acetate (SnAc₂), cesium acetate (CsAc), formamidinium acetate (FAAc), methylammonium acetate (MAAc), and phenylethylammonium acetate (PEAAc).

7. The semiconductor layer of claim 1, wherein the iodide-based compound comprises at least one selected from the group consisting of RbI, KI, NaI, and LiI.

8. The semiconductor layer of claim 1, wherein a molar ratio (mₐ:m_{b}, mol:mol) of the first additive (a) to the second additive (b) is in a range of 10:90 to 90:10.

9. The semiconductor layer of claim 1, wherein the Sn-based perovskite is represented by Structural Formula 1,
A₍₁₋ₐ₎(B_{(1-b)}C_{b})ₐSn(X_{(1-c)}Y)₃ [Structural Formula 1]
where in Structural Formula 1,
A is cesium (Cs),
B and C are different and each independently methylammonium (MA) or formamidinium (FA),
a is a real number of 0≤a≤1,
b is a real number of 0≤b≤1,
X and Y are different and each independently fluorine (F), chlorine (Cl), bromine (Br), or iodine (I), and
c is a real number of 0≤c≤1.

10. The semiconductor layer of claim 9, wherein the Sn-based perovskite comprises at least one selected from the group consisting of cesium tin triiodide (CsSnI₃), methylammonium tin triiodide (MASnI₃), formamidinium tin triiodide (FASnI₃), and cesium formamidinium tin triiodide (CsFASnI₃).

11. The semiconductor layer of claim 1, wherein the perovskite complex is applied to a semiconductor layer of at least one selected from the group consisting of a transistor, a solar cell, a light-emitting diode, a photodiode, and a photosensor.

12. The semiconductor layer of claim 1, wherein the semiconductor layer has a thickness in a range of 1 to 100 nm.

13. A perovskite thin film transistor comprising:
a gate electrode 100;
an insulating layer 200 positioned on the gate electrode;
a semiconductor layer 300 positioned on the insulating layer, the semiconductor layer comprising a perovskite complex; and
a source electrode 400 and a drain electrode 500 spaced from each other while being positioned on the semiconductor layer,
wherein the perovskite complex comprises:
a Sn-based perovskite; and
an additive comprising at least one selected from the group consisting of a first additive and a second additive,
the first additive comprises at least one selected from the group consisting of a chloride-based compound and an acetate-based compound, and
the second additive comprises an iodide-based compound.

14. A method of manufacturing a semiconductor layer, the method comprising:
(a) providing a Sn-based perovskite precursor and an additive comprising at least one selected from the group consisting of a first additive and a second additive;
(b) coating a substrate with the Sn-based perovskite precursor and the additive comprising the at least one selected from the group consisting of the first and second additives; and
(c) subjecting the resulting product of (b) to heat treatment to manufacture a semiconductor layer comprising a perovskite complex,
wherein the perovskite complex comprises:
a Sn-based perovskite; and
the additive comprising the at least one selected from the group consisting of the first and second additives,
the first additive comprises at least one selected from the group consisting of a chloride-based compound and an acetate-based compound, and
the second additive comprises an iodide-based compound.

15. The method of claim 14, wherein the perovskite complex comprises 0.1 to 50 mol of the additive based on 100 mol of Sn in the Sn-based perovskite.

16. The method of claim 14, wherein the heat treatment in the (c) is performed at a temperature in a range of room temperature to 330° C.

17. The method of claim 14, wherein the (b) is performed by at least one method selected from the group consisting of thermal evaporation, chemical vapor deposition (CVD), atomic layer deposition (ALD), sputtering, spin coating, bar coating, slot coating, dip coating, spray coating, gravure coating, inkjet coating, dispensing coating, flexography, screen coating, and a combination thereof.

18. The method of claim 14, wherein the (b) is performed by thermal evaporation.

19. The method of claim 14, wherein the (b) comprises:
(b-1) coating the substrate with the Sn-based perovskite precursor; and
(b-2) coating the substrate with the first additive, and
the (b-1) and the (b-2) are performed simultaneously or separately.

20. The method of claim 19, wherein the (b) further comprises (b-3) coating the substrate with the second additive, and
the (b-1), the (b-2), and the (b-3) are performed simultaneously or separately.
